(19) United States
(12) Patent Application Publication
(10) Pub. No.: US 2025/0255142 A1
(43) Pub. Date: Aug. 7, 2025

(54) DISPLAY DEVICE AND METHOD FOR MANUFACTURING THE SAME

(71) Applicant: Samsung Display Co., LTD., Yongin-si (KR)

(72) Inventors: Shin Tack KANG, Yongin-si (KR); Young Min KIM, Yongin-si (KR); Hyun Seok KIM, Yongin-si (KR); Seung Jun YU, Yongin-si (KR)

(21) Appl. No.: 18/807,787

(22) Filed: Aug. 16, 2024

(30) Foreign Application Priority Data
Feb. 6, 2024 (KR) 10-2024-0018079

(51) Int. Cl. H10K 59/80; H10K 59/12; H10K 59/122; H10K 59/131; H10K 59/38; H10K 71/60; H10K 102/00

(52) U.S. Cl. CPC H10K 59/80522; H10K 59/1201; H10K 59/122; H10K 59/131; H10K 59/38; H10K 71/60; H10K 2102/331

(57) ABSTRACT

A display device includes a substrate including a light-emitting area and a non-light-emitting area, a pixel-defining layer at the non-light-emitting area, and defining a first opening, a bank layer above the pixel-defining layer, and defining a second opening, an auxiliary electrode above the bank layer, and entirely covering the bank layer, a first cathode electrode at the light-emitting area, and contacting the auxiliary electrode, and a first quantum dot layer above the first cathode electrode.

### CROSS-REFERENCE TO RELATED APPLICATION

The present application claims priority to, and the benefit of, Korean Patent Application No. 10-2024-0018079, filed on Feb. 6, 2024, in the Korean Intellectual Property Office, the entire disclosure of which is incorporated herein by reference.

### BACKGROUND

### 1. Field

The present disclosure relates to a display device and a method for manufacturing the same.

### 2. Description of the Related Art

As an information society develops, the demand for a display device for displaying an image is increasing in various forms. For example, the display device has been applied to various electronic devices, such as smartphones, digital cameras, laptop computers, navigation devices, and smart televisions. The display devices may be flat panel display devices, such as liquid crystal display devices, field emission display devices, or organic light-emitting display devices. Among the flat panel display devices, the light-emitting display device may include a light-emitting element in which each of the pixels of a display panel may emit light by itself, thereby displaying an image without a backlight unit providing the light to the display panel.

Recently, the display devices have been applied to glasses-type devices to provide virtual reality and augmented reality. For the display device to be applied to the glasses-type device, the display device is suitably implemented in a relatively very small size of two inches or less, but also suitably has high pixel integration to be implemented with high resolution. For example, the display device may have a high pixel integration of 1000 pixels per inch (PPI) or more.

### SUMMARY

Aspects of the present disclosure are to provide a high-resolution and high-efficiency display device, and to simplify a process of manufacturing the high-resolution and high-efficiency display device.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

Details of other embodiments are included in the detailed description and drawings.

According to some embodiments of the present disclosure, a display device includes a substrate including a light-emitting area and a non-light-emitting area, a pixel-defining layer at the non-light-emitting area, and defining a first opening, a bank layer above the pixel-defining layer, and defining a second opening, an auxiliary electrode above the bank layer, and entirely covering the bank layer, a first cathode electrode at the light-emitting area, and contacting the auxiliary electrode, and a first quantum dot layer above the first cathode electrode.

The bank layer may be entirely surrounded by the pixel-defining layer and the auxiliary electrode.

The bank layer may have a reverse tapered shape.

A height of the bank layer in a direction substantially perpendicular to the substrate may be greater than a height of the pixel-defining layer.

The bank layer may include an organic material, wherein the auxiliary electrode includes a conductive metal.

The first cathode electrode may be electrically connected to the auxiliary electrode.

The display device may further include a light-emitting layer between the substrate and the first cathode electrode in a direction substantially perpendicular to the substrate, an organic pattern above the bank layer, including a same material as the light-emitting layer, and spaced apart from the light-emitting layer, and an electrode pattern above the organic pattern, including a same material as the first cathode electrode, and spaced apart from the first cathode electrode.

The display device may further include a first inorganic layer above the first cathode electrode and the electrode pattern, wherein the auxiliary electrode includes a first portion contacting the light-emitting layer, a second portion contacting the organic pattern, and a third portion contacting the first inorganic layer, and wherein the first portion and the second portion are spaced apart from each other with the third portion interposed therebetween.

The display device may further include a second inorganic layer above the first inorganic layer, wherein, in a portion overlapping the light-emitting area, the first quantum dot layer is entirely surrounded by the first inorganic layer and the second inorganic layer.

The display device may further include a second cathode electrode spaced apart from the first cathode electrode with the bank layer interposed therebetween, and electrically connected to the first cathode electrode through the auxiliary electrode, and
a second quantum dot layer above the second cathode electrode.

The first quantum dot layer and the second quantum dot layer may be spaced apart from each other in a direction substantially parallel to the substrate with the organic pattern and the electrode pattern interposed therebetween.

The first quantum dot layer and the second quantum dot layer may include a quantum dot material.

The display device may further include a residual pattern between the substrate and the pixel-defining layer in the direction substantially perpendicular to the substrate, wherein the residual pattern overlaps the auxiliary electrode in the direction substantially perpendicular to the substrate.

The residual pattern may contact the light-emitting layer, and may include an oxide semiconductor.

The display device may further include a color filter above the first quantum dot layer, wherein the light-emitting layer is configured to emit light to an exterior through the first quantum dot layer and the color filter.

The first opening may be entirely surrounded by the second opening in a plan view.

According to some embodiments of the present disclosure, a method for manufacturing a display device includes forming an anode electrode above a substrate, forming a sacrificial layer above the anode electrode, forming a pixel-defining layer above the sacrificial layer, forming a bank layer having an inverse tapered shape above the pixel-defining layer, forming an auxiliary electrode entirely covering the bank layer, forming a photoresist above the auxiliary electrode, removing a portion of the auxiliary electrode, the pixel-defining layer, and the sacrificial layer, forming a light-emitting layer and a cathode electrode above the anode electrode, forming a first inorganic layer above the cathode electrode, forming a quantum dot layer above the first inorganic layer, and forming a second inorganic layer covering the first inorganic layer and the quantum dot layer.

In the removing of the portion of the auxiliary electrode, the auxiliary electrode may expose a portion of the anode electrode.

The forming of the light-emitting layer and the cathode electrode may be performed without using a separate fine metal mask.

The cathode electrode may contact, and may be electrically connected to, the auxiliary electrode.

As the display device according to one or more embodiments includes a bank structure positioned to overlap a non-light-emitting area, a light-emitting element positioned to overlap each light-emitting area may be formed without a separate fine metal mask. Accordingly, the display device of one or more embodiments may provide a high-resolution display device and suitability of manufacturing the high-resolution display device.

In addition, as the display device of one or more embodiments includes a reflective layer on a side surface of the bank structure and a quantum dot layer positioned to overlap each light-emitting element, a high-efficiency display device may be provided.

However, the aspects of the embodiments are not restricted to the one set forth herein. The above and other aspects of the embodiments will become more apparent to one of ordinary skill in the art to which the embodiments pertain by referencing the claims.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating an electronic device according to one or more embodiments;

FIG. 2 is a perspective view illustrating a display device included in the electronic device according to one or more embodiments;

FIG. 3 is a schematic cross-sectional view of the display device of FIG. 2;

FIG. 4 is a plan view illustrating an arrangement of light-emitting areas in a display area of FIG. 3;

FIG. 5 is a cross-sectional view of a display area taken along the line X1-X1′ of FIG. 4;

FIG. 6 is an enlarged cross-sectional view of a display element layer and a quantum dot layer positioned in a portion overlapping a first light-emitting area in FIG. 5;

FIG. 7 is an enlarged cross-sectional view of a display element layer and a quantum dot layer positioned in a portion overlapping a non-light-emitting area between a first light-emitting area and a second light-emitting area in FIG. 5; and

FIGS. 8 to 16 are cross-sectional views schematically illustrating a method for manufacturing the display element layer and the quantum dot layer in FIG. 5.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group including X, Y, and Z,” and “at least one selected from the group including X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be substantially perpendicular to one another, or may represent different directions that are not substantially perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

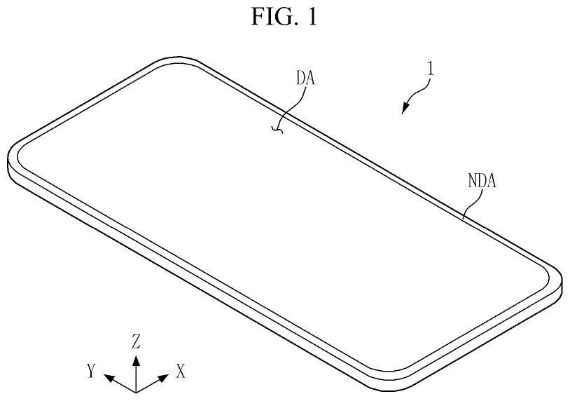

FIG. 1 is a schematic perspective view of an electronic device 1 according to one or more embodiments.

Referring to FIG. 1, an electronic device 1 displays a moving image or a still image. The electronic device 1 may refer to any electronic device that provides a display screen. For example, electronic device 1 may include televisions, laptop computers, monitors, billboards, Internet of things, mobile phones, smartphones, tablet personal computers (PCs), electronic watches, smartwatches, watch phones, head mounted displays, mobile communication terminals, electronic notebooks, electronic books, portable multimedia players (PMPs), navigation, game consoles, digital cameras, camcorders, and the like that provide the display screen.

In FIG. 1, a first direction (X-axis direction), a second direction (Y-axis direction), and a third direction (Z-axis direction) are defined. The first direction (X-axis direction) and the second direction (Y-axis direction) may be substantially perpendicular to each other, the first direction (X-axis direction) and the third direction (Z-axis direction) may be substantially perpendicular to each other, and the second direction (Y-axis direction) and the third direction (Z-axis direction) may be substantially perpendicular to each other. It may be understood that the first direction (X-axis direction) means a horizontal direction in the drawings, the second direction (Y-axis direction) means a vertical direction in the drawings, and the third direction (Z-axis direction) means upper and lower directions in the drawings, that is, a thickness direction. In the following specification, unless otherwise specified, the term “direction” may refer to both directions toward both sides extending along the direction. In addition, when both “directions” extending to both sides need to be distinguished from each other, one side will be referred to as “one side in the direction” and the other side will be referred to as “the other side in the direction”. In FIG. 1, a direction in which an arrow indicating a direction is directed is referred to as one side, and an opposite direction thereof is referred to as the other side.

Hereinafter, for convenience of explanation, in referring to surfaces of the electronic device 1 or each member constituting the electronic device 1, one surface facing one side in a direction in which an image is displayed, that is, in the third direction (Z-axis direction) is referred to as an upper surface, and an opposite surface of the one surface is referred to as the other surface. However, the present disclosure is not limited thereto, and the one surface and the other surface of the member may be referred to as a front surface and a rear surface, respectively, or may also be referred to as a first surface or a second surface. In addition, in describing a relative position of each member of the electronic device 1, one side in the third direction (Z-axis direction) may be referred to as an upper side and the other side in the third direction (Z-axis direction) may be referred to as a lower side.

A shape of the electronic device 1 may be variously changed. For example, the electronic device 1 may have a shape, such as a rectangle with a long width, a rectangle with a long length, a square, a quadrangle with rounded corners (vertices), other polygons, or a circle.

The electronic device 1 may include a display area DA and a non-display area NDA. The display area DA is an area in which a screen may be displayed, and the non-display area NDA is an area in which a screen is not displayed. The display area DA may also be referred to as an active area, and the non-display area NDA may also be referred to as a non-active area. The display area DA may generally occupy the center of the electronic device 1.

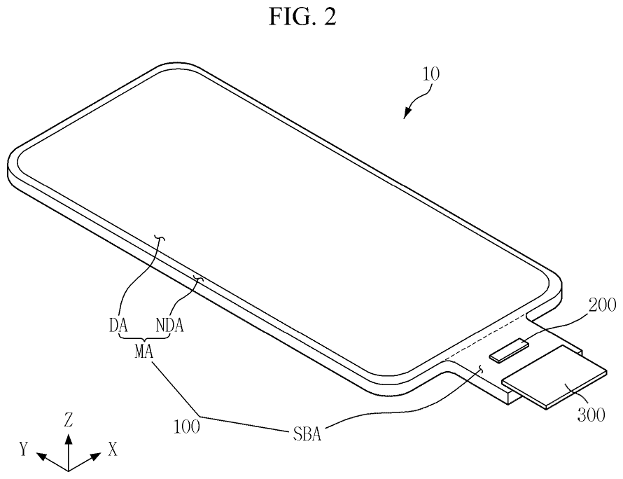

FIG. 2 is a perspective view illustrating a display device 10 included in the electronic device 1 according to one or more embodiments.

Referring to FIG. 2, the electronic device 1 according to one or more embodiments may include a display device 10. The display device 10 may provide a screen displayed by the electronic device 1. Examples of the display device 10 may include an inorganic light-emitting diode display device, an organic light-emitting display device, a quantum dot light-emitting display device, a plasma display device, and a field emission display device. Hereinafter, it is illustrated that an organic light-emitting diode display device is used as an example of the display device, but the present disclosure is not limited thereto and may also be applied to other display devices as long as the same technical idea is applicable thereto.

The display device 10 may have a planar shape similar to that of the electronic device 1. For example, the display device 10 may have a shape similar to a rectangle having a short side in a first direction (X-axis direction) and a long side in a second direction (Y-axis direction). A corner where the short side in the first direction (X-axis direction) and the long side in the second direction (Y-axis direction) meet may be rounded to have a curvature, but is not limited thereto and may also be formed at a right angle. The planar shape of the display device 10 is not limited to the quadrangle, and may be formed similarly to other polygons, circles, or ovals.

The display device 10 includes a display panel 100, a display driver 200, and a circuit board 300.

The display panel 100 may include a main area MA and a sub-area SBA.

The main area MA may include a display area DA including pixels displaying an image, and a non-display area NDA positioned around the display area DA.

The display area DA may emit light from a plurality of light-emitting areas or a plurality of openings to be described later. For example, the display panel 100 may include a pixel circuit including switching elements, a pixel-defining layer defining the light-emitting areas or the openings, and a self-light-emitting element. For example, the self-light-emitting element may include, but is not limited to, at least one of an organic light-emitting diode (LED) including an organic light-emitting layer, a quantum dot LED including a quantum dot light-emitting layer, an inorganic LED including an inorganic semiconductor, or a micro LED. In the following drawings, it is illustrated that the self-light-emitting element is an organic light-emitting diode.

The non-display area NDA may be an area outside the display area DA. The non-display area NDA may be defined as an edge area of the main area MA of the display panel 100.

The sub-area SBA may be an area extending from one side of the main area MA. The sub-area SBA may include a flexible material that may be bent, folded, rolled, or the like. For example, when the sub-area SBA is bent, the sub-area SBA may overlap the main area MA in a thickness direction (e.g., a third direction (Z-axis direction)). The sub-area SBA may include the display driver 200 and a pad portion connected to the circuit board 300. In one or more other embodiments, the sub-area SBA may be omitted, and the display driver 200 and the pad portion may be positioned in the non-display area NDA.

The display driver 200 may output signals and voltages for driving the display panel 100. The display driver 200 may be formed as an integrated circuit (IC) and mounted on the display panel 100 by a chip-on-glass (COG) method, a chip-on-plastic (COP) method, or an ultrasonic bonding method. For example, the display driver 200 may be positioned in the sub-area SBA, and may overlap the main area MA in the thickness direction by bending of the sub-area SBA. As another example, the display driver 200 may be mounted on the circuit board 300.

The circuit board 300 may be attached onto the pad portion of the display panel 100 using an anisotropic conductive film (ACF). The circuit board 300 may be a flexible film, such as a flexible printed circuit board, a printed circuit board, or a chip on film.

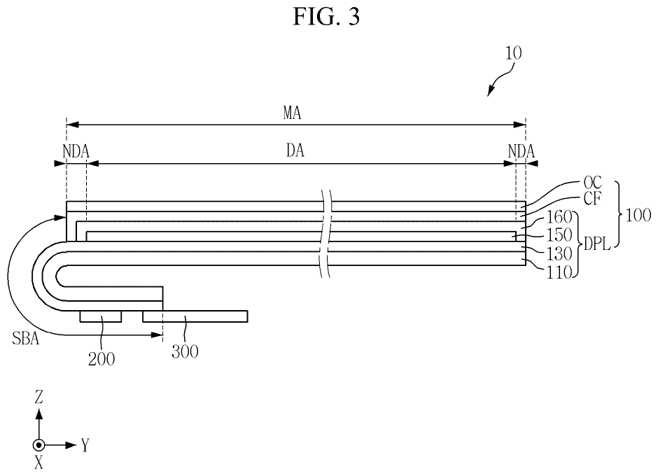

FIG. 3 is a schematic cross-sectional view of the display device 10 of FIG. 2.

Referring to FIG. 3, the display panel 100 may include a display layer DPL, a color filter layer CF, and an overcoating layer OC. The display layer DPL may include a substrate 110, a thin film transistor layer 130, a display element layer 150, and a quantum dot layer 160.

The substrate 110 may be a base substrate or a base member. The substrate 110 may be a flexible substrate that may be bent, folded, rolled, or the like. For example, the substrate 110 may include a polymer resin, such as polyimide PI, but is not limited thereto. In one or more other embodiments, the substrate 110 may include a glass material or a metal material.

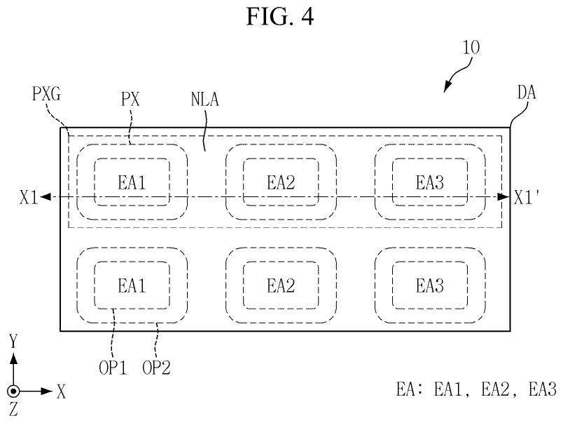

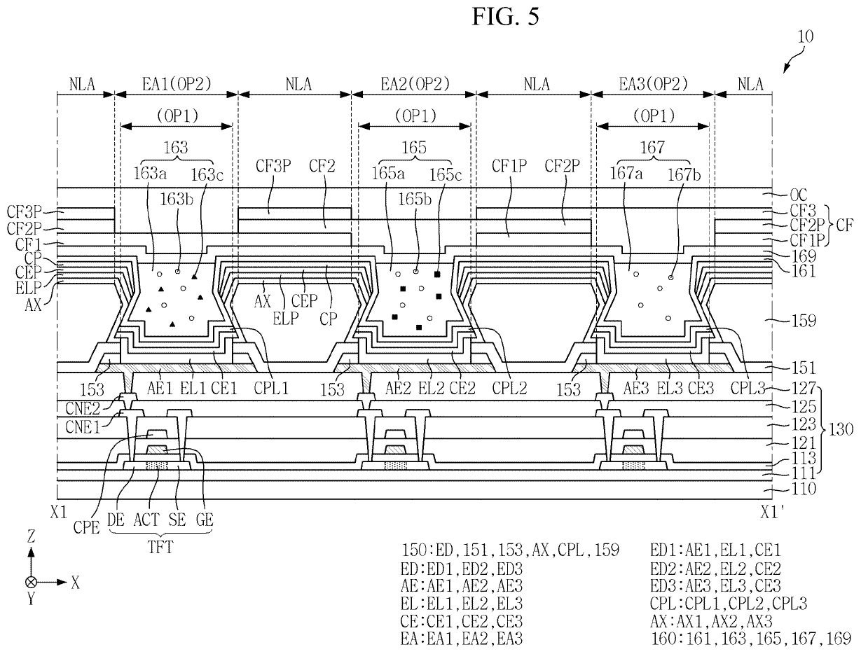

The thin film transistor layer 130 may be positioned on the substrate 110. The thin film transistor layer 130 may be positioned in the display area DA, the non-display area NDA, and the sub-area SBA. The thin film transistor layer 130 may include a plurality of thin film transistors (“TFT” in FIG. 5) constituting a pixel (“PX” in FIG. 4).

The display element layer 150 may be positioned on the thin film transistor layer 130. The display element layer 150 may overlap the display area DA. The display element layer 150 may include a self-emitting element, and the self-emitting element may emit light.

The quantum dot layer 160 may be positioned on the display element layer 150. The quantum dot layer 160 may overlap the display area DA and the non-display area NDA. The quantum dot layer 160 may change or transmit a wavelength of light emitted from the display element layer 150, and may protect the display element layer 150 from external oxygen and moisture.

The color filter layer CF may be positioned on the quantum dot layer 160. The color filter layer CF may overlap the display area DA and the non-display area NDA. The color filter layer CF may transmit or reflect a portion of light emitted from the display element layer 150 and the quantum dot layer 160. In addition, the color filter layer CF may absorb a portion of light introduced from the outside of the display device 10 to reduce reflected light caused by external light.

The overcoating layer OC may be positioned on the color filter layer CF. The overcoating layer OC may overlap the display area DA and the non-display area NDA. A level difference in a lower structure of the overcoating layer OC may be flattened.

As illustrated in FIG. 3, a portion of the display layer DPL overlapping the sub-area SBA may be bent. When a portion of the display layer DPL is bent, the display driver 200 and the circuit board 300 may overlap the main area MA in the third direction (Z-axis direction).

FIG. 4 is a plan view illustrating an arrangement of light-emitting areas EA in the display area DA of FIG. 3.

Referring to FIG. 4, the display area DA according to one or more embodiments may include a plurality of first to third light-emitting areas EA1, EA2, and EA3 and a non-light-emitting area NLA. The non-light-emitting area NLA may surround the plurality of first to third light-emitting areas EA1, EA2, and EA3.

The non-light-emitting area NLA may block each light emitted from the plurality of first to third light-emitting areas EA1, EA2, and EA3. As a result, the non-light-emitting area NLA may assist in reducing or preventing mixture of light emitted from the first to third light-emitting areas EA1, EA2, and EA3.

The light-emitting areas EA may include a first light-emitting area EA1, a second light-emitting area EA2, and a third light-emitting area EA3 that emit light of different colors. Each of the first to third light-emitting areas EA1, EA2, and EA3 may emit red, green, or blue light, respectively, and the color of light emitted from each of the first to third light-emitting areas EA1, EA2, and EA3 may vary depending on the type of quantum dot layer 160 and/or color filter layer CF, which will be described later. In one or more embodiments, the first light-emitting area EA1 may emit red light of a first color, the second light-emitting area EA2 may emit green light of a second color, and the third light-emitting area EA3 may emit blue light of a third color, but the present disclosure is not limited thereto. It is illustrated in the drawing that the size and shape of each of the first to third light-emitting areas EA1, EA2, and EA3 are the same, but the present disclosure is not limited thereto. The size and shape of each of the first to third light-emitting areas EA1, EA2, and EA3 may be freely adjusted according to required characteristics.

The plurality of first to third light-emitting areas EA1, EA2, and EA3 may be defined by a first opening OP1 and a second opening OP2. In plan view, the first opening OP1 may be entirely surrounded by the second opening OP2.

In some embodiments, at least one first light-emitting area EA1, at least one second light-emitting area EA2, and at least one third light-emitting area EA3 positioned to be adjacent to each other may form one pixel group PXG. The pixel group PXG may be a minimum unit that emits white light. However, the type and/or number of the first to third light-emitting areas EA1, EA2, and EA3 constituting the pixel group PXG may vary depending on the embodiments.

FIG. 5 is a schematic cross-sectional view of the display device 10 taken along the line X1-X1′ of FIG. 4. FIG. 5 illustrates a schematic cross-section of the display layer DPL of the display device 10 according to one or more embodiments. Because the substrate 110 was described with reference to FIG. 3, the description thereof will be omitted.

Referring to FIG. 5, the thin film transistor layer 130 may be positioned on the substrate 110. The thin film transistor layer 130 may include a first buffer layer 111, a thin film transistor TFT, a gate-insulating layer 113, a first interlayer insulating layer 121, a capacitor electrode CPE, a second interlayer insulating layer 123, a first connection electrode CNE1, a first via layer 125, a second connection electrode CNE2, and a second via layer 127.

The first buffer layer 111 may be positioned on the substrate 110. The first buffer layer 111 may include an inorganic film capable of reducing or preventing permeation of air or moisture. For example, the first buffer layer 111 may include a plurality of inorganic films alternately stacked.

The thin film transistor TFT may be positioned on the first buffer layer 111, and may constitute a pixel circuit connected to each of the plurality of pixels. As an example, the thin film transistor TFT may be a driving transistor or a switching transistor of the pixel circuit. The thin film transistor TFT may include an active layer ACT, a source electrode SE, a drain electrode DE, and a gate electrode GE.

The active layer ACT may be positioned on the first buffer layer 111. The active layer ACT may overlap the gate electrode GE in the third direction (Z-axis direction), and may be insulated from the gate electrode GE by the gate-insulating layer 113. In a portion of the active layer ACT, a material of the active layer ACT may become a conductor to form the source electrode SE and the drain electrode DE.

The gate electrode GE may be positioned on the gate-insulating layer 113. The gate electrode GE may overlap the active layer ACT with the gate-insulating layer 113 interposed therebetween.

The gate-insulating layer 113 may be positioned on the active layer ACT. The gate-insulating layer 113 may cover the active layer ACT and the first buffer layer 111, and may insulate the active layer ACT and the gate electrode GE from each other. The gate-insulating layer 113 may include a contact hole through which the first connection electrode CNE1 penetrates.

The first interlayer insulating layer 121 may cover the gate electrode GE and the gate-insulating layer 113. The first interlayer insulating layer 121 may include a contact hole through which the first connection electrode CNE1 penetrates. The contact hole of the first interlayer insulating layer 121 may be connected to the contact hole of the gate-insulating layer 113 and a contact hole of the second interlayer insulating layer 123.

The capacitor electrode CPE may be positioned on the first interlayer insulating layer 121. The capacitor electrode CPE may overlap the gate electrode GE in the third direction (Z-axis direction). The capacitor electrode CPE and the gate electrode GE may form a capacitance.

The second interlayer insulating layer 123 may cover the capacitor electrode CPE and the first interlayer insulating layer 121. The second interlayer insulating layer 123 may include a contact hole through which the first connection electrode CNE1 penetrates. The contact hole of the second interlayer insulating layer 123 may be connected to the contact hole of the first interlayer insulating layer 121 and the contact hole of the gate-insulating layer 113.

The first connection electrode CNE1 may be positioned on the second interlayer insulating layer 123. The first connection electrode CNE1 may electrically connect the drain electrode DE of the thin film transistor TFT and the second connection electrode CNE2 to each other. The first connection electrode CNE1 may be inserted into the contact holes formed in the first interlayer insulating layer 121, the second interlayer insulating layer 123, and the gate-insulating layer 113, and may be in contact with the drain electrode DE of the thin film transistor TFT.

The first via layer 125 may cover the first connection electrode CNE1 and the second interlayer insulating layer 123. The first via layer 125 may planarize a lower structure. The first via layer 125 may include a contact hole through which the second connection electrode CNE2 penetrates.

The second connection electrode CNE2 may be positioned on the first via layer 125. The second connection electrode CNE2 may be inserted into the contact hole formed in the first via layer 125, and may be in contact with the first connection electrode CNE1. The second connection electrode CNE2 may electrically connect the first connection electrode CNE1 and first to third anode electrodes AE1, AE2, and AE3 to each other.

The second via layer 127 may cover the second connection electrode CNE2 and the first via layer 125. The second via layer 127 may include a contact hole through which the first to third anode electrodes AE1, AE2, and AE3 penetrate.

The display element layer 150 may be positioned on the second via layer 127. The display element layer 150 may include a light-emitting element ED, a pixel-defining layer 151, a residual pattern 153, an auxiliary electrode AX, a capping layer CPL, and a bank layer 159.

The light-emitting element ED according to one or more embodiments may include a first light-emitting element ED1 positioned in a portion overlapping the first light-emitting area EA1, a second light-emitting element ED2 positioned in a portion overlapping the second light-emitting area EA2, and a third light-emitting element ED3 positioned in a portion overlapping the third light-emitting area EA3. The first light-emitting element ED1 may include a first anode electrode AE1, a first light-emitting layer EL1, and a first cathode electrode CE1, the second light-emitting element ED2 may include a second anode electrode AE2, a second light-emitting layer EL2, and a second cathode electrode CE2, and the third light-emitting element ED3 may include a third anode electrode AE3, a third light-emitting layer EL3, and a third cathode electrode CE3. The first to third light-emitting elements ED1, ED2, and ED3 may be spaced apart from each other by a pixel-defining layer 151 and a bank layer 159, which will be described later.

The anode electrode AE according to one or more embodiments may be positioned on the second via layer 127. The anode electrode AE may be electrically connected to the drain electrode DE of the thin film transistor TFT through the first and second connection electrodes CNE1 and CNE2.

The anode electrode AE according to one or more embodiments may include a first anode electrode AE1 positioned in the first light-emitting area EA1, a second anode electrode AE2 positioned in the second light-emitting area EA2, and a third anode electrode AE3 positioned in the third light-emitting area EA3. The first anode electrode AE1, the second anode electrode AE2, and the third anode electrode AE3 may be spaced apart from each other on the second via layer 127.

The anode electrode AE according to one or more embodiments may have a stacked film structure in which a material layer having a high work function, made of indium tin oxide (ITO), indium zinc oxide (IZO), zinc oxide (ZnO), or indium oxide (In₂O₃) and a reflective material layer made of silver (Ag), magnesium (Mg), aluminum (AI), platinum (Pt), lead (Pd), palladium (Pd), gold (Au), nickel (Ni), neodymium (Nd), iridium (Ir), chromium (Cr), lithium (Li), calcium (Ca), or mixtures thereof are stacked. As an example, the first to third anode electrodes AE1, AE2, and AE3 may have a multi-layer structure of ITO/Mg, ITO/MgF, ITO/Ag, and ITO/Ag/ITO, but are not limited thereto. The residual pattern 153 will be described later.

The pixel-defining layer 151 according to one or more embodiments may be positioned on the second via layer 127 and the anode electrode AE in a portion overlapping the non-light-emitting area NLA. The pixel-defining layer 151 may separate and insulate the first to third anode electrodes AE1, AE2, and AE3 from each other. The pixel-defining layer 151 may define a first opening OP1, and may expose the anode electrode AE in a portion overlapping the first opening OP1. In other words, the pixel-defining layer 151 may surround the first opening OP1.

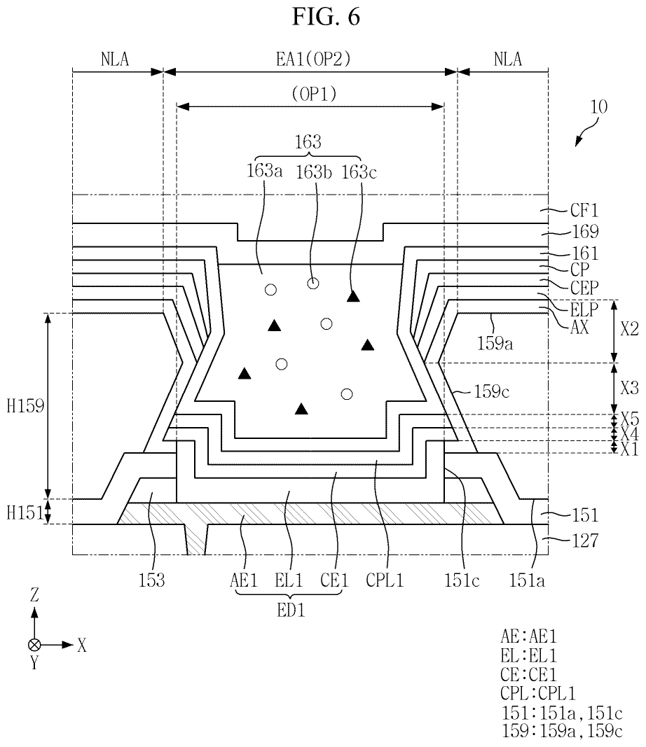

The bank layer 159 according to one or more embodiments may be positioned on the pixel-defining layer 151 in a portion overlapping the non-light-emitting area NLA. The bank layer 159 may separate and insulate the first to third light-emitting elements ED1, ED2, and ED3 from each other. The bank layer 159 according to one or more embodiments may define a second opening OP2 (e.g., see FIG. 6). The bank layer 159 may surround the second opening OP2.

The bank layer 159 according to one or more embodiments may have an inverse tapered shape. Therefore, the light-emitting layer EL and the cathode electrode CE according to one or more embodiments may be formed in a portion overlapping each of the first to third light-emitting areas EA1, EA2, and EA3 without a separate fine metal mask. The manufacturing process will be described later.

The residual pattern 153 according to one or more embodiments may be positioned between the anode electrode AE and the pixel-defining layer 151 in the third direction (Z-axis direction). The residual pattern 153 will be described later.

The light-emitting layer EL according to one or more embodiments may be positioned on the anode electrode AE. The light-emitting layer EL may include a first light-emitting layer EL1, a second light-emitting layer EL2, and a third light-emitting layer EL3 located in the first to third light-emitting areas EA1, EA2, and EA3, respectively. The first to third light-emitting layers EL1, EL2, and EL3 according to one or more embodiments may be spaced apart from the first to third light-emitting areas EA1, EA2, and EA3 by the pixel-defining layer 151 and the bank layer 159.

The light-emitting layer EL according to one or more embodiments may include a tandem structure. In other words, the light-emitting layer EL according to one or more embodiments may include a structure in which a plurality of light-emitting organic layers are stacked. As an example, the light-emitting layer EL may include a first light-emitting organic layer, a second light-emitting organic layer, and a third light-emitting organic layer that are sequentially stacked, and the first light-emitting organic layer, the second light-emitting organic layer, and the third light-emitting organic layer may overlap each other in the third direction (Z-axis direction). The first to third light-emitting organic layers may emit the same color or different colors. For example, the light-emitting layer EL may emit blue light or white light. However, the number of organic light-emitting layers, the stacked order of the organic light-emitting layers, and the emission wavelength band of the organic light-emitting layers are not limited to thereto.

The cathode electrode CE according to one or more embodiments may be positioned on the light-emitting layer EL. The cathode electrode CE according to one or more embodiments may include a first cathode electrode CE1 positioned in the first light-emitting area EA1, a second cathode electrode CE2 positioned in the second light-emitting area EA2, and a third cathode electrode CE3 positioned in the third light-emitting area EA3. The first to third cathode electrodes CE1, CE2, and CE3 may be spaced apart from each other with the pixel-defining layer 151 and the bank layer 159 interposed therebetween.

The cathode electrode CE may include a transparent conductive material. As an example, the cathode electrode CE may include a material layer having a small work function, such as Li, Ca, LiF/Ca, LiF/Al, Al, Mg, Ag, Pt, Pd, Ni, Au, Nd, Ir, Cr, BaF, Ba, or a compound or mixture thereof (e.g., a mixture of Ag and Mg, etc.). The cathode electrode CE may further include a transparent metal oxide layer positioned on the material layer having the small work function.

The capping layer CPL according to one or more embodiments may be positioned on the cathode electrode CE. The capping layer CPL may reduce or prevent damage to the plurality of light-emitting elements ED from due to external air. In addition, the capping layer CPL may reduce or prevent the likelihood of the plurality of light-emitting elements ED being peeled off during the process of manufacturing the display device 10.

The capping layer CPL may include a first capping layer CPL1 positioned in a portion overlapping the first light-emitting area EA1, a second capping layer CPL2 positioned in a portion overlapping the second light-emitting area EA2, and a third capping layer CPL3 positioned in a portion overlapping the third light-emitting area EA3. The first to third capping layers CPL1, CPL2, and CPL3 may be spaced apart from each other with the pixel-defining layer 151 and the bank layer 159 interposed therebetween.

The capping layer CPL may include an inorganic insulating material. As an example, the capping layer CPL may include aluminum oxide, titanium oxide, tantalum oxide, hafnium oxide, zinc oxide, silicon oxide, silicon nitride, and/or silicon oxynitride.

The auxiliary electrode AX according to one or more embodiments may be positioned on the bank layer 159. The auxiliary electrode AX may entirely cover the bank layer 159, and may be in contact with the bank layer 159. In addition, a portion of the auxiliary electrode AX may be in contact with the light-emitting layer EL and the cathode electrode CE.

The auxiliary electrode AX may electrically connect the first to third cathode electrodes CE1, CE2, and CE3. In other words, the first to third cathode electrodes CE1, CE2, and CE3 that are spaced apart from each other may be electrically connected through the auxiliary electrode AX. In addition, the auxiliary electrode AX according to one or more embodiments may reflect light incident from the quantum dot layer 160, which will be described later, toward the auxiliary electrode AX.

The organic pattern ELP, the electrode pattern CEP, and the capping pattern CP according to one or more embodiments will be described later.

The quantum dot layer 160 according to one or more embodiments may be positioned on the display element layer 150. The quantum dot layer 160 may include a first inorganic layer 161, a first quantum dot layer 163, a second quantum dot layer 165, a third quantum dot layer 167, and a second inorganic layer 169.

The first inorganic layer 161 according to one or more embodiments may be positioned on the capping layer CPL and the capping pattern CP. The first inorganic layer 161 may protect the light-emitting element ED from oxygen and moisture permeating into the light-emitting element ED. The first inorganic layer 161 may be formed to have a substantially uniform thickness along a profile of the lower structure. Therefore, the first inorganic layer 161 according to one or more embodiments may include a level difference in a portion overlapping the light-emitting area EA and the non-light-emitting area NLA.

The first inorganic layer 161 may include an inorganic insulating material. As an example, the first inorganic layer 161 may include any one of aluminum oxide, titanium oxide, tantalum oxide, hafnium oxide, zinc oxide, silicon oxide, silicon nitride, or silicon oxynitride.

The first quantum dot layer 163, the second quantum dot layer 165, and the third quantum dot layer 167 according to one or more embodiments may be positioned on the first inorganic layer 161. The first quantum dot layer 163 may be positioned in a portion overlapping the first light-emitting area EA1, the second quantum dot layer 165 may be positioned in a portion overlapping the second light-emitting area EA2, and the third quantum dot layer 167 may be positioned in a portion overlapping the third light-emitting area EA3. The first to third quantum dot layers 163, 165, and 167 may be spaced apart in the first direction (X-axis direction) with the bank layer 159 interposed therebetween.

Hereinafter, although the configurations between the first quantum dot layer 163, the second quantum dot layer 165, and the third quantum dot layer 167 are distinguished by adding ordinal numbers “first,” “second,” and “third” to each configuration while naming a base resin, scatterers, and/or wavelength shifters included in the first quantum dot layer 163, the second quantum dot layer 165, and the third quantum dot layer 167, the ordinal numbers of “first,” “second,” and “third” written in conjunction with each component of the first quantum dot layer 163, second quantum dot layer 165, and third quantum dot layer 167 are not limited thereto, and may be written in conjunction with each component by changing their order.

The first quantum dot layer 163 according to one or more embodiments may be positioned on the first inorganic layer 161 in a portion overlapping the first light-emitting area EA1. The first quantum dot layer 163 might not overlap the non-light-emitting area NLA. The first quantum dot layer 163 may convert or shift a peak wavelength of incident light to light having another corresponding peak wavelength, and may emit the converted or shifted light. As an example, the first quantum dot layer 163 may convert source light provided from the first light-emitting element ED1 into red light having a peak wavelength in the range of about 610 nm to about 650 nm, and may emit the converted red light.

The first quantum dot layer 163 may include a first base resin 163a, and first scatterers 163b and first wavelength shifters 163c dispersed in the first base resin 163a.

The first base resin 163a according to an may be made of a material having high light transmittance. In one or more embodiments, the first base resin 163a may be made of an organic material. For example, the first base resin 163a may include an organic material, such as an epoxy resin, an acrylic resin, a cardo resin, or an imide resin.

The first scatterer 163b according to one or more embodiments may have a refractive index that is different from that of the first base resin 163a, and may form an optical interface with the first base resin 163a. The first scatterers 163b may scatter light in a random direction regardless of an incident direction of the incident light without substantially converting a wavelength of light transmitted through the first quantum dot layer 163.

The first scatterers 163b may be metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), or the like, and examples of a material of the organic particle may include an acrylic resin, a urethane resin, and the like.

The first wavelength shifter 163c according to one or more embodiments may convert or shift the peak wavelength of the incident light into another corresponding peak wavelength. For example, the first wavelength shifter 163c may convert light provided from the first light-emitting element ED1 into red light having a single peak wavelength in the range of about 610 nm to about 650 nm, and may emit the red light.

The first wavelength shifter 163c may include a quantum dot material. The quantum dot may be a semiconductor nano-crystal material, and may have a corresponding bandgap according to the composition and size thereof to absorb light and then emit light having a unique wavelength. Examples of the semiconductor nano-crystal of the quantum dot may include Group IV nano-crystal, Group II-VI compound nano-crystal, Group III-V compound nano-crystal, Group IV-VI nano-crystal, or a combination thereof.

The Group II-VI compound may be selected from the group including a binary compound selected from the group including CdSe, CdTe, ZnS, ZnSe, ZnTe, ZnO, HgS, HgSe, HgTe, MgSe, MgS, or mixtures thereof; a ternary compound selected from the group including InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or mixtures of thereof; and a quaternary compound selected from the group including HgZnTeS, CdZnSeS, CdZnSeTe, CdZnSTe, CdHgSeS, CdHgSeTe, CdHgSTe, HgZnSeS, HgZnSeTe, HgZnSTe, or mixtures thereof.

The Group III-V compound may be selected from the group including a binary compound selected from the group including GaN, GaP, GaAs, GaSb, AlN, AlP, AlAs, AlSb, InN, InP, InAs, InSb, or mixtures thereof; a ternary compound selected from the group including GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, or mixtures thereof; and a quaternary compound selected from the group including GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or mixtures thereof.

The Group IV-VI compound may be selected from the group including a binary compound selected from the group including SnS, SnSe, SnTe, PbS, PbSe, PbTe, or mixtures thereof; a ternary compound selected from the group including SnSeS, SnSeTe, SnSTe, PbSeS, PbSeTe, PbSTe, SnPbS, SnPbSe, SnPbTe, or mixtures thereof; and a quaternary compound selected from the group including SnPbSSe, SnPbSeTe, SnPbSTe, or mixtures thereof. A Group IV element may be selected from the group including Si, Ge, or mixtures thereof. A Group IV compound may be a binary compound selected from the group including SiC, SiGe, or mixtures thereof.

In this case, the binary compound, the ternary compound, or the quaternary compound may be present in a particle at a substantially uniform concentration, or may be present in the same particle in a state of partially different concentration distributions. In addition, the quantum dot may have a core/shell structure in which one quantum dot surrounds another quantum dot. An interface between the core and the shell may have a concentration gradient in which a concentration of the element present in the shell decreases toward the center.

According to one or more embodiments, the quantum dot may have a core-shell structure including a core including the above-described nano-crystal and a shell surrounding the core. The shell of the quantum dot may serve as a protective layer for maintaining semiconductor properties by reducing or preventing chemical modification of the core and/or a charging layer for imparting electrophoretic properties to the quantum dot. The shell may be a single layer or a multi-layer. Examples of the shell of the quantum dot may include a metal or non-metal oxide, a semiconductor compound, or a combination thereof.

For example, examples of the metal or non-metal oxide may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO or a ternary compound, such as MgAl₂O₄, CoFe₂O₄, NiFe₂O₄, or CoMn₂O₄, but the present disclosure is not limited thereto.

In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like, but the present disclosure is not limited thereto.

The light emitted by the first wavelength shifter 163c may have an emission wavelength spectrum full width of half maximum (FWHM) of about 45 nm or less, or about 40 nm or less, or about 30 nm or less, and through this, color purity and color reproducibility of colors displayed by the display device 10 may be further improved. In addition, the light emitted by the first wavelength shifter 163c may be emitted toward several directions regardless of the incident direction of the incident light. Through this, side visibility of the first color displayed in the first light-emitting area EA1 may be improved.

The second quantum dot layer 165 according to one or more embodiments may be positioned on the first inorganic layer 161 in a portion overlapping the second light-emitting area EA2. The second quantum dot layer 165 might not overlap the non-light-emitting area NLA. The second quantum dot layer 165 may convert or shift a peak wavelength of incident light to light having another corresponding peak wavelength, and may emit the converted or shifted light. As an example, the second quantum dot layer 165 may convert source light provided from the second light-emitting element ED2 into green light in the range of about 510 nm to about 550 nm, and may emit the green light.

The second quantum dot layer 165 according to one or more embodiments may include a second base resin 165a, and second scatterers 165b and second wavelength shifters 165c dispersed in the second base resin 165a.

The second base resin 165a may be made of a material having high light transmittance. Because the materials and characteristics of the second base resin 165a according to one or more embodiments are substantially the same as, or similar to, those of the first base resin 163a, overlapping descriptions will be omitted.

The second scatterer 165b may have a refractive index that is different from that of the second base resin 165a, and may form an optical interface with the second base resin 165a. Because the materials and characteristics of the second scatterer 165b according to one or more embodiments are substantially the same as, or similar to, those of the first scatterer 163b, overlapping descriptions will be omitted.

The second wavelength shifter 165c may convert or shift the peak wavelength of the incident light into another corresponding peak wavelength. The second wavelength shifter 165c according to one or more embodiments may convert light provided from the second light-emitting element ED2 into green light having a single peak wavelength in the range of about 510 nm to about 550 nm, and may emit the green light.

The second wavelength shifter 165c may include a quantum dot material. Because the materials and characteristics of the second wavelength shifter 165c are substantially the same as, or similar to, those of the first wavelength shifter 163c, overlapping descriptions will be omitted. However, a particle size of the quantum dots constituting the first wavelength shifter 163c may be greater than a particle size of the quantum dots constituting the second wavelength shifter 165c.

The third quantum dot layer 167 according to one or more embodiments may be positioned on the first inorganic layer 161 in a portion overlapping the third light-emitting area EA3. The third quantum dot layer 167 may scatter and transmit source light provided from the third light-emitting element ED3.

The third quantum dot layer 167 may further include a third base resin 167a, and third scatterers 167b dispersed in the third base resin 167a.

The third base resin 167a may be made of a material having high light transmittance. Because the materials and characteristics of the third base resin 167a according to one or more embodiments are substantially the same as, or similar to, those of the first base resin 163a, overlapping descriptions will be omitted.

The third scatterer 167b may have a refractive index that is different from that of the third base resin 167a, and may form an optical interface with the third base resin 167a. Because the materials and characteristics of the third scatterer 167b according to one or more embodiments are substantially the same as, or similar to, those of the first scatterer 163b, overlapping descriptions will be omitted.

The second inorganic layer 169 according to one or more embodiments may be positioned on the first inorganic layer 161, the first quantum dot layer 163, the second quantum dot layer 165, and the third quantum dot layer 167. The second inorganic layer 169 may entirely cover the first inorganic layer 161, the first quantum dot layer 163, the second quantum dot layer 165, and the third quantum dot layer 167. The second inorganic layer 169 may reduce or prevent permeation of impurities, such as moisture or air, from the outside to damage or contaminate the first quantum dot layer 163, the second quantum dot layer 165, and the third quantum dot layer 167.

The second inorganic layer 169 may be made of an inorganic material. For example, the second inorganic layer 169 may include silicon nitride, aluminum nitride, zirconium nitride, titanium nitride, hafnium nitride, tantalum nitride, silicon oxide, aluminum oxide, titanium oxide, tin oxide, and/or silicon oxynitride.

The color filter layer CF according to one or more embodiments may be positioned on the quantum dot layer 160. The color filter layer CF may block or absorb a portion of light emitted from the display element layer 150 and the quantum dot layer 160. The color filter layer CF may include a first color filter CF1, a second color filter CF2, and/or a third color filter CF3.

The first color filter CF1 may be positioned on the second inorganic layer 169 in a portion overlapping the first light-emitting area EA1. The first color filter CF1 may overlap the first light-emitting element ED1 and the first quantum dot layer 163. In other words, the source light provided from the first light-emitting element ED1 may be incident on the first color filter CF1 through the first quantum dot layer 163.

The first color filter CF1 may selectively transmit light of a first color (e.g., red light), and may block or absorb light of a second color (e.g., green light) and light of a third color (e.g., blue light).

The first color filter CF1 may block or absorb a portion of the light emitted from the first light-emitting element ED1 and the first quantum dot layer 163. For example, a portion of the source light provided from the first light-emitting element ED1 may not be converted into the red light by the first wavelength shifter 163c. However, a portion of the source light that is not converted to the red light may be blocked by the first color filter CF1 positioned on an upper side. On the other hand, the red light converted by the first quantum dot layer 163 among the source light may be transmitted through the first color filter CF1, and may be emitted to the outside. Therefore, a user located outside the display device 10 may recognize the red light in a portion overlapping the first light-emitting area EA1.

For example, the first color filter CF1 may be a red color filter, and may include a red colorant, such as a red dye or a red pigment. Herein, a colorant is a concept including both a dye and a pigment.

A first color pattern CF1P may be spaced from the first color filter CF1, and may be positioned on the second inorganic layer 169 in a portion overlapping the non-light-emitting area NLA. The first color pattern CF1P may be positioned in a portion that does not overlap the light-emitting area EA, and that overlaps the non-light-emitting area NLA.

The second color filter CF2 may be positioned on the first color filter CF1 in a portion overlapping the second light-emitting area EA2. The second color filter CF2 may overlap the second light-emitting element ED2 and the second quantum dot layer 165. In other words, the source light provided from the second light-emitting element ED2 may be incident on the second color filter CF2 through the second quantum dot layer 165.

The second color filter CF2 may selectively transmit light of a second color (e.g., green light), and may block or absorb light of a first color (e.g., red light) and light of a third color (e.g., blue light).

The second color filter CF2 may block or absorb a portion of the light emitted from the second light-emitting element ED2 and the second quantum dot layer 165. For example, a portion of the source light provided from the second light-emitting element ED2 may not be converted into the green light by the second quantum dot layer 165. However, a portion of the source light that is not converted to the green light may be blocked by the second color filter CF2 positioned on an upper side. On the other hand, the green light converted by the second quantum dot layer 165 among the source light may be transmitted through the second color filter CF2, and may be emitted to the outside. Therefore, a user located outside the display device 10 may recognize the green light in a portion overlapping the second light-emitting area EA2.

For example, the second color filter CF2 may be a green color filter, and may include a green colorant, such as a green dye or a green pigment.

A second color pattern CF2P may be spaced apart from the second color filter CF2 and may be positioned on the first color filter CF1 and the first color pattern CF1P. The second color pattern CF2P might not overlap the light-emitting area EA, and may overlap the non-light-emitting area NLA.

However, the colors specified by the first color filter CF1 and the second color filter CF2 are not limited thereto, and the first color filter CF1 may correspond to light of a second color (e.g., green light), and the second color filter CF2 may correspond to light of a first color (e.g., red light).

The third color filter CF3 may be positioned on the second color filter CF2 in a portion overlapping the non-light-emitting area NLA. The third color filter CF3 may overlap the third light-emitting element ED3 and the third quantum dot layer 167. In other words, the source light provided from the third light-emitting element ED3 may be incident on the third color filter CF3 through the third quantum dot layer 167.

The third color filter CF3 may selectively transmit light of a third color (e.g., blue light), and may block or absorb light of a first color (e.g., red light) and light of a second color (e.g., green light).

The third color filter CF3 may block or absorb a portion of the light emitted from the third light-emitting element ED3 and the third quantum dot layer 167. For example, a portion of the source light provided from the third light-emitting element ED3 may be transmitted through the third quantum dot layer 167, and may be incident on the third color filter CF3. In this case, light other than the blue light among the source light may be blocked by the third color filter CF3 positioned at an upper side. Therefore, a user located outside the display device 10 may recognize the blue light in a portion overlapping the third light-emitting area EA3.

For example, the third color filter CF3 may be a blue color filter, and may include a blue colorant, such as a blue dye or a blue pigment.

A third color pattern CF3P may be spaced apart from the third color filter CF3, and may be positioned on the second color filter CF2 and the second color pattern CF2P. The second color pattern CF2P might not overlap the non-light-emitting area NLA, and may overlap the light-emitting area EA.

The overcoating layer OC according to one or more embodiments may be positioned on the color filter layer CF. The overcoating layer OC may planarize an upper side of the color filter layer CF.

The overcoating layer OC may be made of an organic material. For example, the overcoating layer OC may include an acrylic resin, a methacrylate resin, a polyisoprene, an imide resin, a vinyl resin, an epoxy resin, a urethane resin, a cellulose resin, a perylene resin, and/or the like.

FIG. 6 is an enlarged cross-sectional view of a display element layer 150 and a quantum dot layer 160 positioned in a portion overlapping a first light-emitting area EA1 in FIG. 5.

Referring to FIG. 6, the residual pattern 153 according to one or more embodiments may be positioned between the pixel-defining layer 151 and the first anode electrode AE1 in the third direction (Z-axis direction). The residual pattern 153 according to one or more embodiments may be positioned in contact with both sides of the first light-emitting layer EL1 in the first direction (X-axis direction).

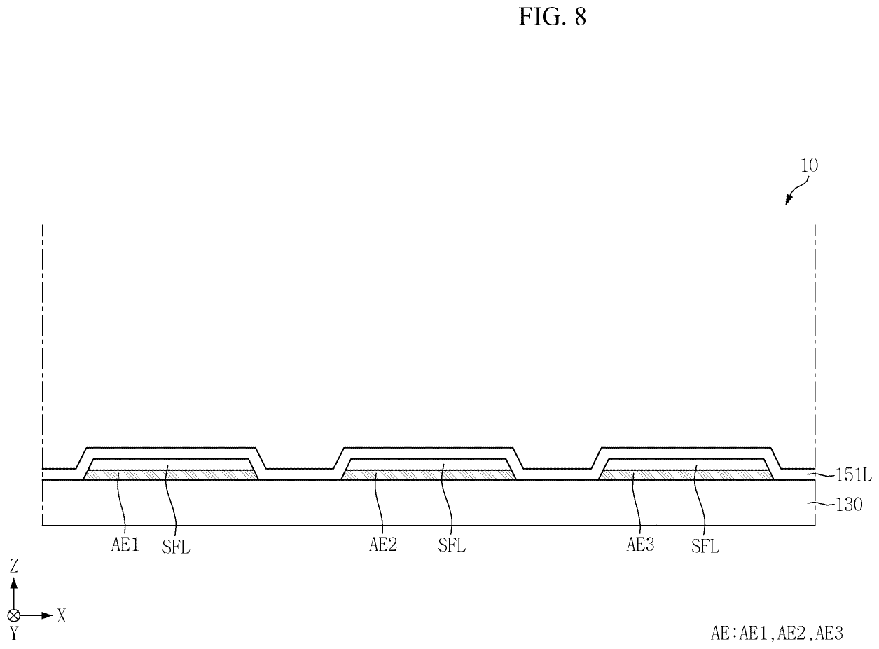

The display device 10 according to one or more embodiments may include a sacrificial layer (‘SFL’ in FIG. 8) on the anode electrode AE during the manufacturing process. The sacrificial layer SFL may be located between the pixel-defining layer 151 and the anode electrode AE, and then may be partially removed by a subsequent etching process. In this case, a portion of the sacrificial layer SFL that has not been removed may remain as the residual pattern 153 between the pixel-defining layer 151 and the anode electrode AE. The manufacturing process will be described later.

The residual pattern 153 according to one or more embodiments may include an oxide semiconductor. As an example, the residual pattern 153 may include at least one of indium gallium zinc oxide (IGZO), zinc tin oxide (ZTO), or indium tin oxide (IZO).

The pixel-defining layer 151 according to one or more embodiments may be positioned in contact with the second via layer 127 and the first anode electrode AE1. The pixel-defining layer 151 may be in contact with the anode electrode AE, the residual pattern 153, the first emitting layer EL1, and the auxiliary electrode AX in a portion overlapping the first emitting area EA1, and may be in contact with the bank layer 159 in a portion overlapping the non-light-emitting area NLA.

The pixel-defining layer 151 may include an inorganic insulating material, and may include, for example, at least one of silicon nitride, silicon oxynitride, silicon oxide, titanium oxide, aluminum oxide, tantalum oxide, hafnium oxide, zinc oxide, or an amorphous silicon layer, but is not limited thereto.

In some embodiments, the pixel-defining layer 151 may include an upper surface 151a and a side surface 151c. The upper surface 151a of the pixel-defining layer 151 may be one surface facing the bank layer 159, and the side surface 151c of the pixel-defining layer 151 may be one surface facing the first opening OP1. A portion of the upper surface 151a of the pixel-defining layer 151 may be covered by the auxiliary electrode AX, and may be in contact with the auxiliary electrode AX. In addition, the side surface 151c of the pixel-defining layer 151 may be entirely covered by the first light-emitting layer EL1, and may be in contact with the first light-emitting layer EL1.

The bank layer 159 according to one or more embodiments may contact the pixel-defining layer 151.

In some embodiments, the bank layer 159 according to one or more embodiments may include an upper surface 159a and a side surface 159c. The upper surface 159a of the bank layer 159 may be one surface facing the second inorganic layer 169, and the side surface 159c of the bank layer 159 may be one surface facing the first opening OP1.

The side surface 159c of the bank layer 159 may be more depressed than the side surface 151c of the pixel-defining layer 151 in the first direction (X-axis direction). In other words, the side surface 151c of the pixel-defining layer 151 according to one or more embodiments may have a shape that protrudes more in the first direction (X-axis direction) toward the first light-emitting area EA1 than the side surface 159c of the bank layer 159. In addition, the upper surface 159a and the side surface 159c of the bank layer 159 may be entirely covered by the auxiliary electrode AX, and may be entirely in contact with the auxiliary electrode AX. In other words, the upper surface 159a and the side surface 159c of the bank layer 159 may be surrounded by the auxiliary electrode AX.

The bank layer 159 may include an organic light-blocking material, and may include, for example, an acrylic resin, a methacrylate resin, a polyisoprene, a vinyl resin, an epoxy resin, a urethane resin, a cellulose resin, and/or a perylene resin. The dye or pigment may include carbon black, etc.

In some embodiments, a height H151 of the pixel-defining layer 151 may be lower than a height H159 of the bank layer 159.

The auxiliary electrode AX according to one or more embodiments may cover, or overlap, the upper surface 151a of the pixel-defining layer 151 along with the upper surface 159a and the side surface 159c of the bank layer 159, and may be in contact with the upper surface 151a of the pixel-defining layer 151 along with the upper surface 159a and the side surface 159c of the bank layer 159. The auxiliary electrode AX may surround the first opening OP1. That is, the auxiliary electrode AX may expose the first opening OP1.

The auxiliary electrode AX may be electrically connected to the first cathode electrode CE1 and may reflect light incident from the first quantum dot layer 163 toward the auxiliary electrode AX.

The auxiliary electrode AX may be a conductive metal with reflective properties. As an example, the auxiliary electrode AX may include any one of Al, Cu, Ag, Au, Mg, Pt, Pd, Ni, Nd, Ir, Cr, BaF, or Ba.

In some embodiments, the auxiliary electrode AX may include a first portion x1, a second portion x2, a third portion x3, a fourth portion x4, and a fifth portion x5, depending on a structure that is in contact with in a direction toward the first opening OP1. The first portion x1 may be a portion in contact with the light-emitting layer EL, the second portion x2 may be a portion in contact with the organic pattern ELP, and the third portion x3 may be a portion in contact with the first inorganic layer 161. The first portion x1 and the second portion x2 may be spaced apart from each other with the third portion x3 interposed therebetween. In addition, the fourth portion x4 may be a portion in contact with the cathode electrode CE, and the fifth portion x5 may be a portion in contact with the capping layer CPL. The cathode electrode CE and the auxiliary electrode AX may be electrically connected through the fourth portion x4, and/or the fifth portion x5 may also be omitted, in one or more embodiments.

The organic pattern ELP according to one or more embodiments may be positioned on the auxiliary electrode AX in a portion overlapping the bank layer 159. The organic pattern ELP according to one or more embodiments may surround the first opening OP1.

As described above, the light-emitting layer EL according to one or more embodiments may be formed through the deposition and photo pattern process without using the separate fine metal mask in the manufacturing process. Therefore, the material forming the light-emitting layer EL may be deposited not only on the anode electrode AE but also on the bank layer 159. That is, as the bank layer 159 according to one or more embodiments is formed in an inverse tapered shape, the organic pattern ELP according to one or more embodiments may be formed in a state where the material forming the light-emitting layer EL deposited on the bank layer 159 is disconnected from the material forming the light-emitting layer EL deposited on the anode electrode AE. Therefore, the organic pattern ELP may include the same material as the light-emitting layer EL, and may be spaced apart from the light-emitting layer EL. In other words, as the display device 10 according to one or more embodiments includes the organic pattern ELP on the bank layer 159, it may be seen that the process of forming the light-emitting layer EL is performed as the photo pattern process. However, depending on the process, the organic pattern ELP may also be removed.

The electrode pattern CEP according to one or more embodiments may be positioned on the organic pattern ELP in a portion overlapping the bank layer 159. The electrode pattern CEP according to one or more embodiments may surround the first opening OP1. A stacking relationship between the electrode pattern CEP and the organic pattern ELP may be the same as a stacking relationship between the cathode electrode CE and the light-emitting layer EL.

As described above, the cathode electrode CE according to one or more embodiments may be formed through the deposition and photo pattern process without using the separate fine metal mask in the manufacturing process. Therefore, the material forming the cathode electrode CE may be deposited not only on the anode electrode AE, but also on the bank layer 159. That is, as the bank layer 159 according to one or more embodiments is formed in an inverse tapered shape, the electrode pattern CEP according to one or more embodiments may be formed in a state where the material forming the cathode electrode CE deposited on the bank layer 159 is disconnected from the material forming the cathode electrode CE deposited on the anode electrode AE. Therefore, the electrode pattern CEP may include the same material as the cathode electrode CE, and may be spaced apart from the cathode electrode CE. In other words, as the display device 10 according to one or more embodiments includes the electrode pattern CEP on the bank layer 159, it may be seen that the process of forming the cathode electrode CE is performed as the photo pattern process. However, depending on the process, the electrode pattern CEP may also be removed.

The capping pattern CP according to one or more embodiments may be positioned on the electrode pattern CEP in a portion overlapping the bank layer 159. The capping pattern CP according to one or more embodiments may surround the first opening OP1. A stacking relationship between the capping pattern CP and the electrode pattern CEP may be the same as a stacking relationship between the capping layer CPL and the cathode electrode CE.

As described above, the capping layer CPL according to one or more embodiments may be formed through the deposition and photo pattern process without using the separate fine metal mask in the manufacturing process. Therefore, the material forming the capping layer CPL may be deposited not only on the anode electrode AE, but also on the bank layer 159. That is, as the bank layer 159 according to one or more embodiments is formed in an inverse tapered shape, the capping pattern CP according to one or more embodiments may be formed in a state where the material forming the capping layer CPL deposited on the bank layer 159 is disconnected from the material forming the capping layer CPL deposited on the anode electrode AE. Therefore, the capping pattern CP may include the same material as the capping layer CPL, and may be spaced apart from the capping layer CPL. In other words, as the display device 10 according to one or more embodiments includes the capping pattern CP on the bank layer 159, it may be seen that the process of forming the capping layer CPL is performed as the photo pattern process. However, depending on the process, the capping pattern CP may also be removed.

The first inorganic layer 161 according to one or more embodiments may entirely cover the first capping layer CPL1, the auxiliary electrode AX, and the capping pattern CP in a portion overlapping the first light-emitting area EA1, and may be in contact with the first capping layer CPL1, the auxiliary electrode AX, and the capping pattern CP.

The first quantum dot layer 163 according to one or more embodiments may be positioned in a portion overlapping the first opening OP1, and might not overlap the second opening OP2 and the non-light-emitting area NLA. The first quantum dot layer 163 may be entirely surrounded by the first inorganic layer 161 and the second inorganic layer 169 in a portion overlapping the first light-emitting area EA1. Because the first base resin 163a, and the first scatterers 163b and the first wavelength shifters 163c dispersed in the first base resin 163a that are included in the first quantum dot layer 163 have already been mentioned, the repeated descriptions thereof will be omitted.

The second inorganic layer 169 according to one or more embodiments may cover the first quantum dot layer 163 in a portion overlapping the first opening OP1, and may be in contact with the first quantum dot layer 163. In addition, the second inorganic layer 169 may cover the first inorganic layer 161 in a portion overlapping the second opening OP2 and the non-light-emitting area NLA, and may be in contact with the first inorganic layer 161.

The first inorganic layer 161 and the second inorganic layer 169 according to one or more embodiments may overlap the residual pattern 153, the organic pattern ELP, the electrode pattern CEP, and the capping pattern CP in the third direction (Z-axis direction). Other redundant descriptions will be omitted.

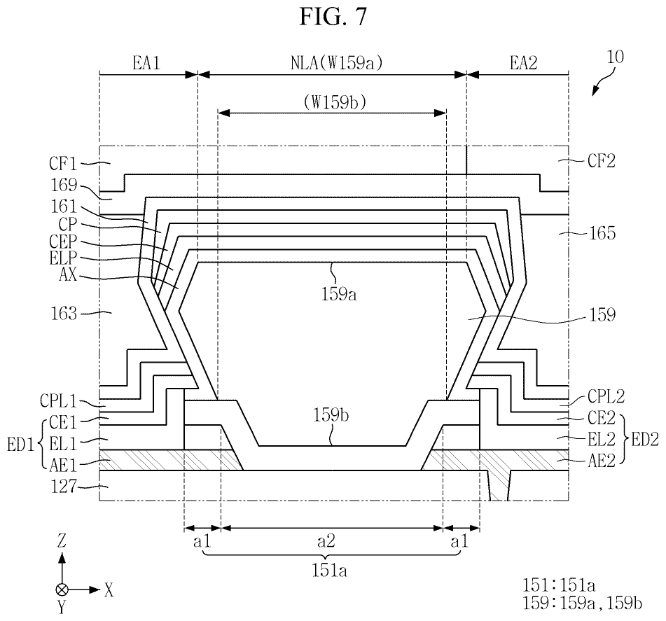

FIG. 7 is an enlarged cross-sectional view of a display element layer 150 and a quantum dot layer 160 positioned in a portion overlapping the non-light-emitting area NLA between the first light-emitting area EA1 and the second light-emitting area EA2 in FIG. 5.

Referring to FIG. 7, the first light-emitting element ED1 and the second light-emitting element ED2 according to one or more embodiments may be spaced apart from each other in the first direction (X-axis direction) by the pixel-defining layer 151 and the bank layer 159. In addition, the residual pattern 153 in contact with the first light-emitting layer EL1, and the residual pattern 153 in contact with the second light-emitting layer EL2, may be spaced apart from each other by the pixel-defining layer 151. In addition, the first quantum dot layer 163 and the second quantum dot layer 165 may be spaced apart from each other in the first direction (X-axis direction) by the bank layer 159.

In some embodiments, the upper surface 151a of the pixel-defining layer 151 may be divided into a first portion a1 and a second portion a2 depending on the portion where the upper surface 151a contacts. The first portion a1 may be a portion in contact with the auxiliary electrode AX, and the second portion a2 may be a portion in contact with the bank layer 159. The first portion a1 may be formed in plural, and the plurality of first portions a1 may be spaced apart from each other with the second portion a2 interposed therebetween.

The bank layer 159 according to one or more embodiments may be entirely surrounded by the auxiliary electrode AX and the pixel-defining layer 151.

In some embodiments, the bank layer 159 may further include a lower surface 159b in addition to the upper surface 159a. As described above, the bank layer 159 according to one or more embodiments may have the inverse tapered shape. Therefore, a width W159a of the upper surface 159a of the bank layer 159 may be greater than a width W159b of the lower surface 159b thereof.

The organic pattern ELP, the electrode pattern CEP, and the capping pattern CP according to one or more embodiments may be positioned in portions overlapping the first light-emitting area EA1, the second light-emitting area EA2, and the non-light-emitting area NLA. The electrode pattern CEP according to one or more embodiments may entirely cover the upper surface of the organic pattern ELP, and the capping pattern CP according to one or more embodiments may entirely cover the upper surface of the electrode pattern CEP.

The first inorganic layer 161 and the second inorganic layer 169 according to one or more embodiments may be in contact with each other in a portion overlapping the non-light-emitting area NLA. Other redundant descriptions will be omitted.

The first color filter CF1 and the second color filter CF2 according to one or more embodiments may overlap the residual pattern 153, the organic pattern ELP, the electrode pattern CEP, and the capping pattern CP in the third direction (Z-axis direction). Other redundant descriptions will be omitted.

FIGS. 8 to 16 are cross-sectional views schematically illustrating a method for manufacturing the display element layer 150 and the quantum dot layer 160 in FIG. 5.

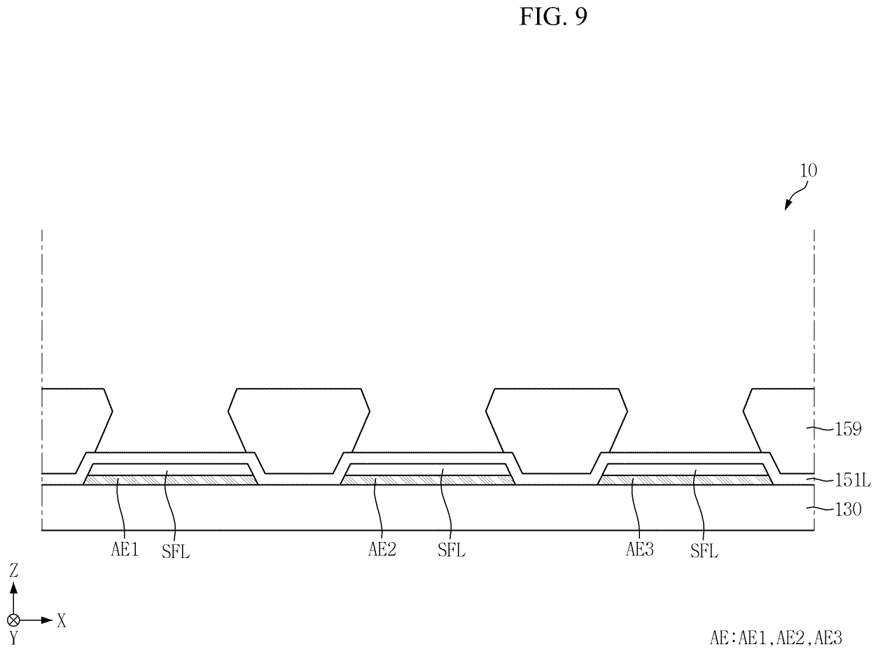

Referring to FIGS. 8 and 9, an anode electrode AE, a sacrificial layer SFL, and a pixel-defining material layer 151L are formed on the thin film transistor layer 130 (as used herein, “formed on” may mean “formed above”). Because the structure of the thin film transistor layer 130 is the same as that described above with reference to FIG. 5, a repeated detailed description thereof will be omitted.

The anode electrode AE may include first to third anode electrodes AE1, AE2, and AE3 spaced apart from each other on the thin film transistor layer 130. A sacrificial layer SFL may be positioned on each of the first to third anode electrodes AE1, AE2, and AE3. The sacrificial layer SFL may help reduce or prevent the likelihood of upper surfaces of the first to third anode electrodes AE1, AE2, and AE3 coming into contact with the pixel-defining material layer 151L.

The pixel-defining material layer 151L may be positioned on the first to third anode electrodes AE1, AE2, and AE3 and the sacrificial layer SFL. The pixel-defining material layer 151L may entirely cover the sacrificial layer SFL and the thin film transistor layer 130. Therefore, the pixel-defining material layer 151L may be in contact with the thin film transistor layer 130 and the sacrificial layer SFL.

Next, as shown in FIG. 9, a bank layer 159 is formed on the pixel-defining material layer 151L through a photo patterning process. The bank layer 159 may be formed in plural, and the plurality of bank layers 159 may be spaced apart from each other in the first direction (X-axis direction). The pixel-defining material layer 151L overlapping between the bank layers 159 spaced apart from each other may be exposed. In the present process, the bank layer 159 may be formed in a reverse tapered shape.

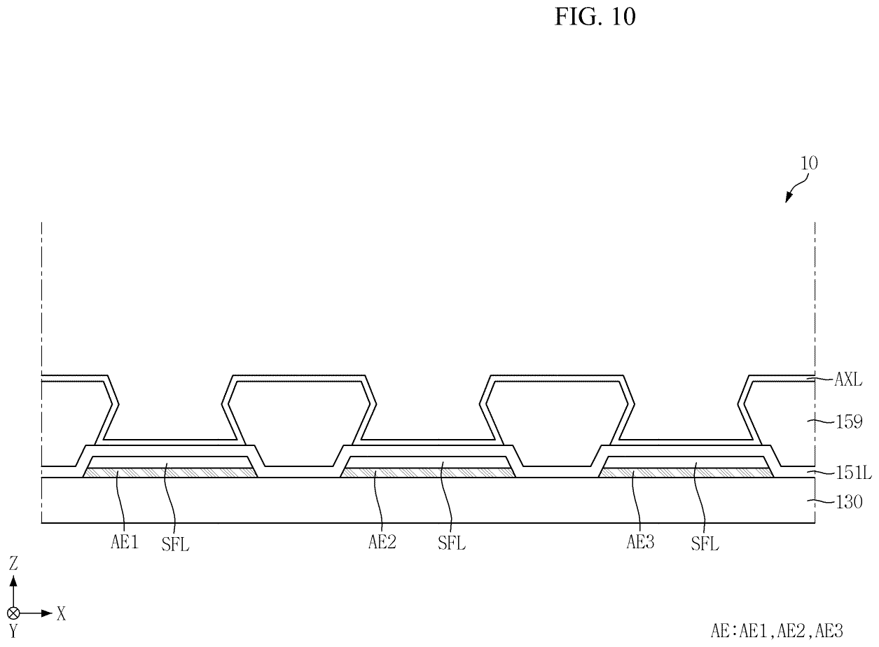

Next, referring to FIGS. 10 to 12, an auxiliary electrode material layer AXL is entirely formed on the pixel-defining material layer 151L and the bank layer 159. The auxiliary electrode material layer AXL may be formed to have a substantially uniform thickness along a profile formed by the pixel-defining material layer 151L and the bank layer 159. The auxiliary electrode material layer AXL may be in contact with the pixel-defining material layer 151L and the bank layer 159.

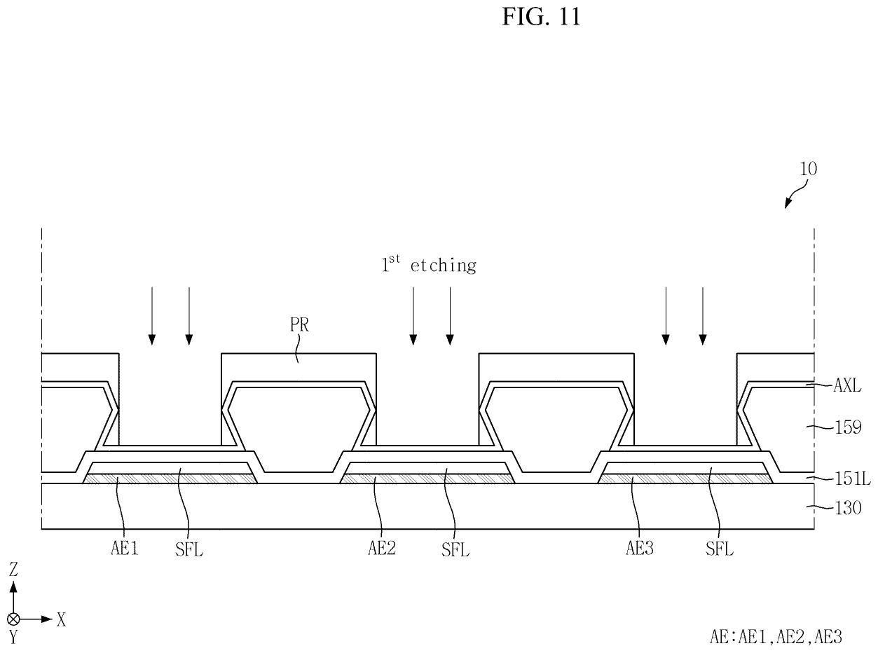

Next, as shown in FIG. 11, a photoresist PR is formed on the auxiliary electrode material layer AXL to overlap the bank layer 159. The photoresist PR may be formed in plural, and the plurality of photoresists PR may be spaced apart from each other. The auxiliary electrode material layer AXL overlapping respective areas between the plurality of photoresists PR, which are spaced apart from each other, may be exposed.

Next, a first etching process is performed using the plurality of photoresists PR as masks. As an example, in the first etching process, a dry etching process and a wet etching process may be alternately performed.

First, the first etching process may be performed as a wet etching process. In the present process, a portion of the auxiliary electrode material layer AXL that does not overlap the photoresist PR may be removed, and a portion of the pixel-defining material layer 151L may be exposed.

Secondly, after the wet etching process, the first etching process may be performed as a dry etching process. In the present process, a portion of the pixel-defining material layer 151L that does not overlap the photoresist PR may be removed, thereby exposing a portion of the sacrificial layer SFL.

Finally, after the dry etching process, the first etching process may be performed as a wet etching process. In the present process, a portion of the sacrificial layer SFL that does not overlap the photoresist PR may be removed, and a portion of the anode electrode AE may be exposed.

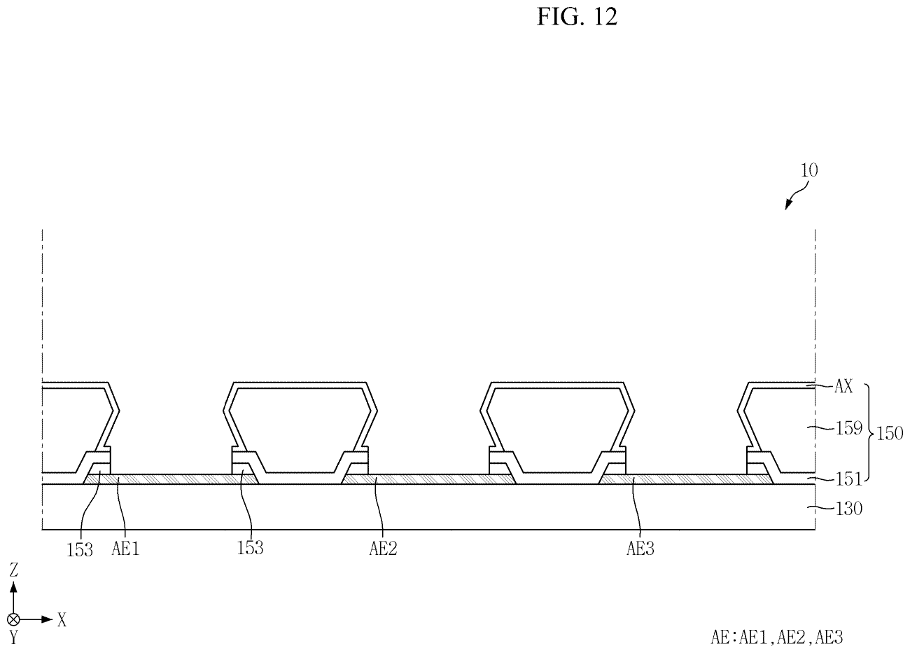

As illustrated in FIG. 12, through the present process, the pixel-defining material layer 151L and the auxiliary electrode material layer AXL may be formed in the form of the pixel-defining layer 151 and the auxiliary electrode AX illustrated in FIG. 5, and the sacrificial layer SFL may be formed in the form of the residual pattern 153 illustrated in FIG. 5.

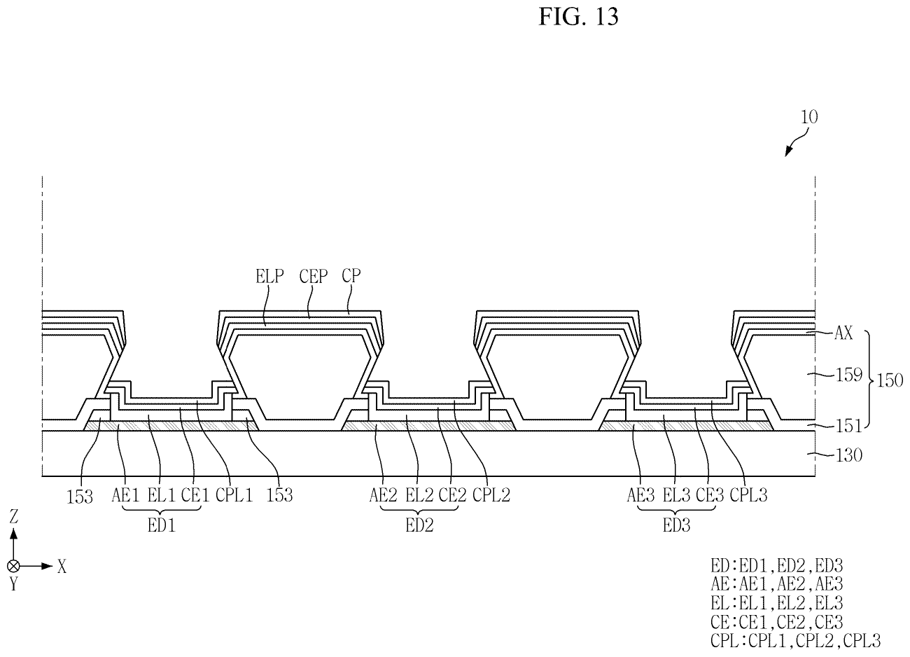

Next, referring to FIG. 13, a light-emitting layer EL, a cathode electrode CE, and a capping layer CPL are deposited on the anode electrode AE.

The process of forming the light-emitting layer EL according to one or more embodiments may be formed by a thermal deposition process. In the process of forming the light-emitting layer EL according to one or more embodiments, as the bank layer 159 is formed in the reverse tapered shape, a first light-emitting layer EL1, a second light-emitting layer EL2, and a third light-emitting layer EL3 may be spaced apart from each other without using a separate fine metal mask. As described above, the first to third light-emitting layers EL1, EL2, and EL3 may be formed in a tandem structure, and as a result, the first to third light-emitting layers EL1, EL2, and EL3 may include the same material.

In the present process, the material forming the light-emitting layer EL may be formed not only on the anode electrode AE, but also on the auxiliary electrode AX positioned to overlap the bank layer 159. The material forming the light-emitting layer EL formed on the auxiliary electrode AX may be formed in the form of the organic pattern ELP illustrated in FIG. 5. Therefore, the organic pattern ELP and the light-emitting layer EL may be spaced apart from each other, and may include the same material.

The process of forming the cathode electrode CE according to one or more embodiments may be formed by a thermal deposition process. In the process of forming the cathode electrode CE according to one or more embodiments, as the bank layer 159 is formed in the reverse tapered shape, a first cathode electrode CE1, a second cathode electrode CE2, and a third cathode electrode CE3 may be spaced apart from each other without using a separate fine metal mask. Therefore, the first to third cathode electrodes CE1, CE2, and CE3 may include the same material.

However, the deposition process of forming the cathode electrode CE according to one or more embodiments may be performed to be inclined at an angle of about 15° or more and about 30° or less in a direction toward the anode electrode AE, compared to the process of forming the light-emitting layer EL. In other words, compared to the deposition process of forming the light-emitting layer EL, the deposition process of forming the cathode electrode CE may be performed to be inclined in a relatively more horizontal direction. As a result, a step coverage of the deposition process of forming the cathode electrode CE may be higher than a step coverage of the deposition process of forming the light-emitting layer EL. Therefore, the cathode electrode CE according to one or more embodiments may be formed not only on the light-emitting layer EL, but also in contact with the auxiliary electrode AX. As a result, the cathode electrode CE and the auxiliary electrode AX according to one or more embodiments may be electrically connected.

In the present process, the material forming the cathode electrode CE may be formed not only on the anode electrode AE, but also on the auxiliary electrode AX positioned to overlap the bank layer 159. The material forming the cathode electrode CE formed on the auxiliary electrode AX may be formed in the form of the electrode pattern CEP illustrated in FIG. 5. The electrode pattern CEP and the cathode electrode CE may be spaced apart from each other, and may include the same material.

The process of the capping layer CPL according to one or more embodiments may be formed by a thermal deposition process or a sputtering deposition process. In the process of forming the capping layer CPL according to one or more embodiments, as the bank layer 159 is formed in the reverse tapered shape, a first capping layer CPL1, a second capping layer CPL2, and a third capping layer CPL3 may be spaced apart from each other without using a separate fine metal mask. Therefore, the first to third capping layers CPL1, CPL2, and CPL3 may include the same material. In one or more embodiments, the process of forming the capping layer CPL may be omitted.

In the present process, the material forming the capping layer CPL may be formed not only on the anode electrode AE, but also on the auxiliary electrode AX positioned to overlap the bank layer 159. The material forming the capping layer CPL formed on the auxiliary electrode AX may be formed in the form of the capping pattern CP illustrated in FIG. 5. The capping pattern CP and the capping layer CPL may be spaced apart from each other, and may include the same material.

Through the present process, the first light-emitting element ED1, the second light-emitting element ED2, and the third light-emitting element ED3 illustrated in FIG. 5 may be formed.

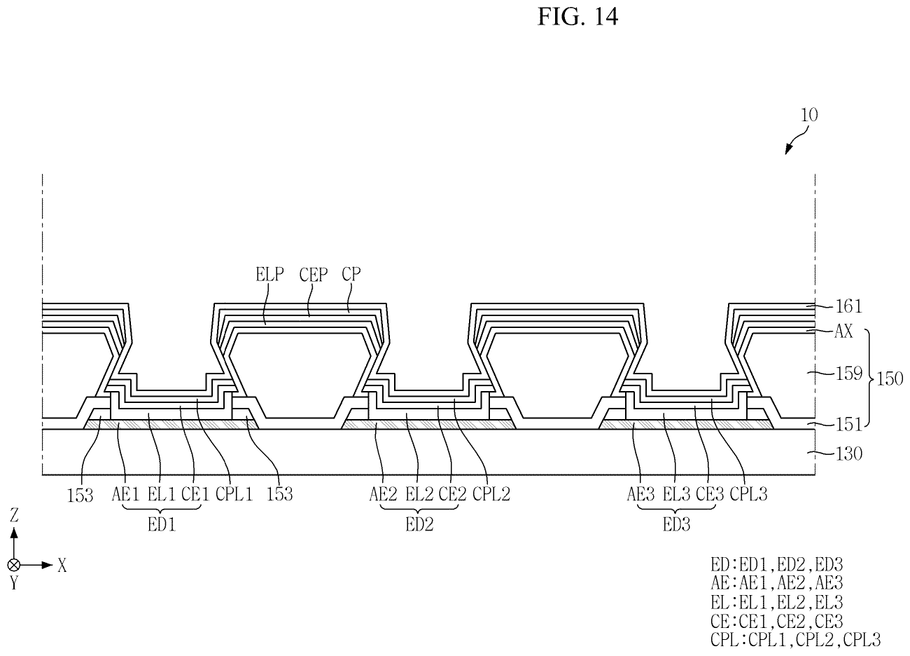

Next, referring to FIGS. 14 to 16, a first inorganic layer 161 that entirely covers the capping layer CPL and the capping pattern CP is formed. The first inorganic layer 161 may be formed by a chemical vapor deposition process, and may be formed with the same thickness along a profile of the lower structure.

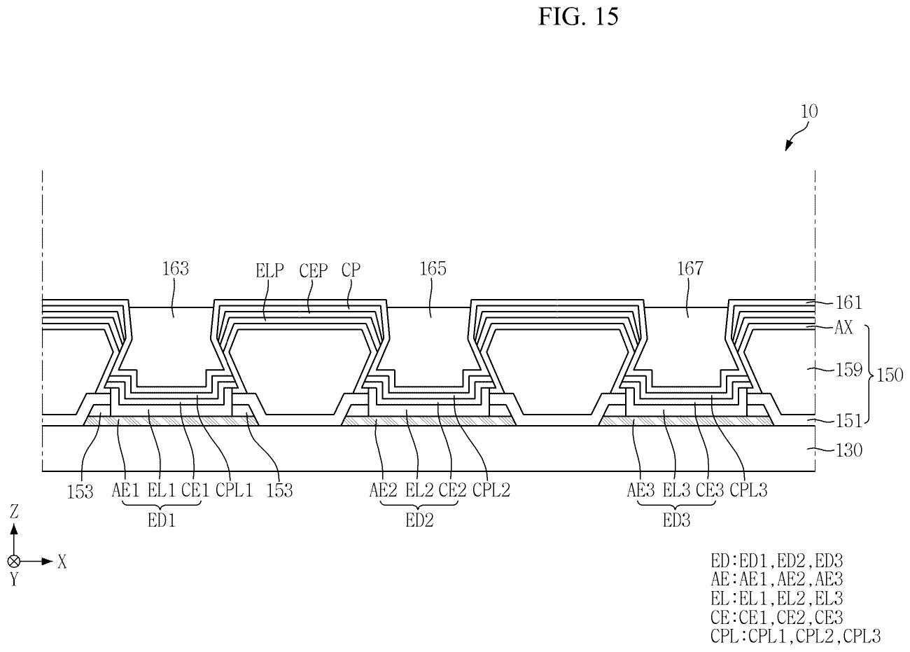

Next, as shown in FIG. 15, a first quantum dot layer 163 is applied on the first inorganic layer 161 positioned in a portion overlapping the first light-emitting element ED1, a second quantum dot layer 165 is applied on the first inorganic layer 161 positioned in a portion overlapping the second light-emitting element ED2, and a third quantum dot layer 167 is applied on the first inorganic layer 161 positioned in a portion overlapping the third light-emitting element ED3. The first to third quantum dot layers 163, 165, and 167 may be applied by an inkjet method.

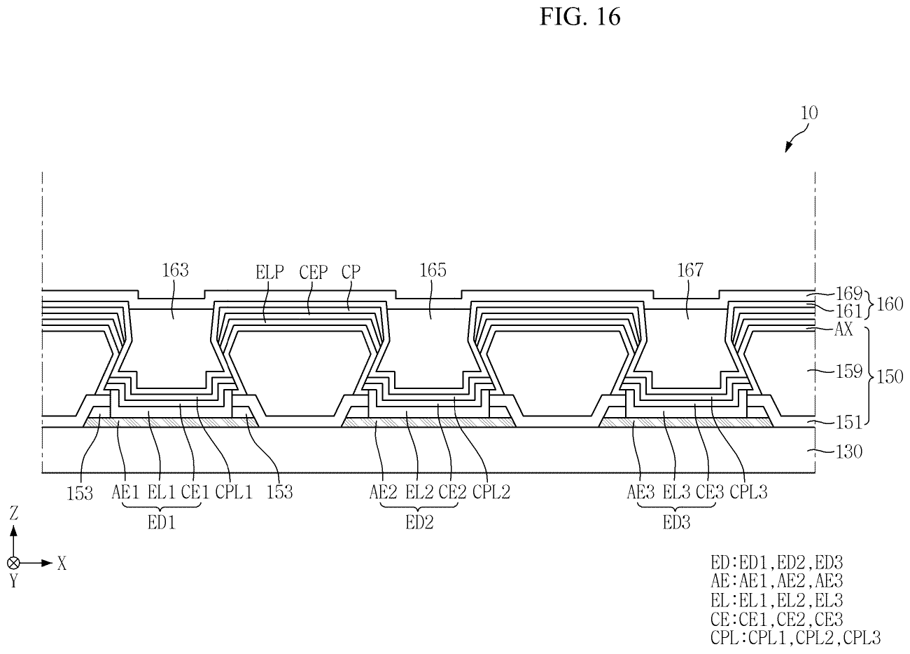

Next, as shown in FIG. 16, a second inorganic layer 169 is entirely formed on the first to third quantum dot layers 163, 165, and 167 and the first inorganic layer 161. The second inorganic layer 169 may be in contact with the first to third quantum dot layers 163, 165, and 167 and the first inorganic layer 161.

As a result, the display element layer 150 and the quantum dot layer 160 illustrated in FIG. 5 may be formed. As the display device 10 according to one or more embodiments includes a bank layer 159 has the inverse tapered shape, a high-resolution light-emitting element ED may be suitably manufactured. In addition, as the display device 10 according to one or more embodiments includes the auxiliary electrode AX that covers the bank layer 159, it may assist in an electrical connection of the cathode electrode CE, and may reflect a portion of the light source scattered from the quantum dot layer 160. Accordingly, the display device 10 according to one or more embodiments may provide a high-efficiency and high-resolution product.

It should be understood that embodiments described herein should be considered in a descriptive sense and not for purposes of limitation. Descriptions of aspects within each embodiment should typically be considered as available for other similar aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a substrate comprising a light-emitting area and a non-light-emitting area;
a pixel-defining layer at the non-light-emitting area, and defining a first opening;
a bank layer above the pixel-defining layer, and defining a second opening;
an auxiliary electrode above the bank layer, and entirely covering the bank layer;
a first cathode electrode at the light-emitting area, and contacting the auxiliary electrode; and
a first quantum dot layer above the first cathode electrode.

2. The display device of claim 1, wherein the bank layer is entirely surrounded by the pixel-defining layer and the auxiliary electrode.

3. The display device of claim 2, wherein the bank layer has a reverse tapered shape.

4. The display device of claim 3, wherein a height of the bank layer in a direction substantially perpendicular to the substrate is greater than a height of the pixel-defining layer.

5. The display device of claim 4, wherein the bank layer comprises an organic material, and
wherein the auxiliary electrode comprises a conductive metal.

6. The display device of claim 1, wherein the first cathode electrode is electrically connected to the auxiliary electrode.

7. The display device of claim 1, further comprising:
a light-emitting layer between the substrate and the first cathode electrode in a direction substantially perpendicular to the substrate;
an organic pattern above the bank layer, comprising a same material as the light-emitting layer, and spaced apart from the light-emitting layer; and
an electrode pattern above the organic pattern, comprising a same material as the first cathode electrode, and spaced apart from the first cathode electrode.

8. The display device of claim 7, further comprising a first inorganic layer above the first cathode electrode and the electrode pattern,
wherein the auxiliary electrode comprises a first portion contacting the light-emitting layer, a second portion contacting the organic pattern, and a third portion contacting the first inorganic layer, and
wherein the first portion and the second portion are spaced apart from each other with the third portion interposed therebetween.

9. The display device of claim 8, further comprising a second inorganic layer above the first inorganic layer,
wherein, in a portion overlapping the light-emitting area, the first quantum dot layer is entirely surrounded by the first inorganic layer and the second inorganic layer.

10. The display device of claim 7, further comprising:
a second cathode electrode spaced apart from the first cathode electrode with the bank layer interposed therebetween, and electrically connected to the first cathode electrode through the auxiliary electrode; and
a second quantum dot layer above the second cathode electrode.

11. The display device of claim 10, wherein the first quantum dot layer and the second quantum dot layer are spaced apart from each other in a direction substantially parallel to the substrate with the organic pattern and the electrode pattern interposed therebetween.

12. The display device of claim 11, wherein the first quantum dot layer and the second quantum dot layer comprise a quantum dot material.

13. The display device of claim 7, further comprising a residual pattern between the substrate and the pixel-defining layer in the direction substantially perpendicular to the substrate,
wherein the residual pattern overlaps the auxiliary electrode in the direction substantially perpendicular to the substrate.

14. The display device of claim 13, wherein the residual pattern contacts the light-emitting layer, and comprises an oxide semiconductor.

15. The display device of claim 7, further comprising a color filter above the first quantum dot layer,
wherein the light-emitting layer is configured to emit light to an exterior through the first quantum dot layer and the color filter.

16. The display device of claim 1, wherein the first opening is entirely surrounded by the second opening in a plan view.

17. A method for manufacturing a display device, the method comprising:
forming an anode electrode above a substrate;
forming a sacrificial layer above the anode electrode;
forming a pixel-defining layer above the sacrificial layer;
forming a bank layer having an inverse tapered shape above the pixel-defining layer;
forming an auxiliary electrode entirely covering the bank layer;
forming a photoresist above the auxiliary electrode;
removing a portion of the auxiliary electrode, the pixel-defining layer, and the sacrificial layer;
forming a light-emitting layer and a cathode electrode above the anode electrode;
forming a first inorganic layer above the cathode electrode;
forming a quantum dot layer above the first inorganic layer; and
forming a second inorganic layer covering the first inorganic layer and the quantum dot layer.

18. The method of claim 17, wherein, in the removing of the portion of the auxiliary electrode, the auxiliary electrode exposes a portion of the anode electrode.

19. The method of claim 18, wherein the forming of the light-emitting layer and the cathode electrode is performed without using a separate fine metal mask.

20. The method of claim 19, wherein the cathode electrode contacts, and is electrically connected to, the auxiliary electrode.
